(19) United States
(12) Patent Application Publication
(10) Pub. No.: US 2023/0171335 A1
(43) Pub. Date: Jun. 1, 2023

(54) SELF-DIAGNOSTIC APPARATUS WITH MAGNETIC COUPLING

(71) Applicant: Korea Electronics Technology Institute, Seongnam-si (KR)

(72) Inventors: Soo Chang CHAE, Seongnam-si (KR); Ki Jin KIM, Hwaseong-si (KR); Kwang Ho AHN, Yongin-si (KR)

(73) Assignee: Korea Electronics Technology Institute, Seongnam-si (KR)

(21) Appl. No.: 17/877,194

(22) Filed: Jul. 29, 2022

(30) Foreign Application Priority Data
Nov. 29, 2021 (KR) 10-2021-0167301

(51) Int. Cl. H04M 1/02; H01Q 3/22; G01R 29/08

(52) U.S. Cl. CPC H04M 1/026; H01Q 3/22; G01R 29/08; H01Q 1/2283

(57) ABSTRACT

There is provided a self-diagnostic apparatus of a magnetic coupling type. The self-diagnostic apparatus according to an embodiment includes: a signal detection line which is magnetic-coupled with an RF signal line through a magnetic coupling loop; and a signal detector configured to detect a size and a phase of an RF signal by detecting a current flowing through the signal detection line. Accordingly, the apparatus grasps and diagnoses respective operation states of channels by itself in a beamforming system, without increasing and a size of the system and degrading performance.

### CROSS-REFERENCE TO RELATED APPLICATION(S) AND CLAIM OF PRIORITY

This application is based on and claims priority under 35 U.S.C. § 119 to Korean Patent Application No. 10-2021-0167301, filed on Nov. 29, 2021, in the Korean Intellectual Property Office, the disclosure of which is herein incorporated by reference in its entirety.

### BACKGROUND

### Field

The disclosure relates to beamforming technology, and more particularly, to an apparatus for diagnosing and calibrating a beamforming system.

### Description of Related Art

In a next-generation beamforming system like a 5^{th} generation (5G) system and a satellite communication system, monolithic microwave integrated circuit (MMIC) elements having various channels are used. A configuration of a beamforming system having a plurality of channels is illustrated in FIG. 1.

FIG. 2 illustrates a self-diagnostic apparatus which is implemented by inserting a coupler between an MMIC and an antenna in order to grasp and diagnose respective operation states of channels by itself in a beamforming system.

However, since the method of configuring the self-diagnostic apparatus by inserting the coupler between the antenna and the MMIC transceiver requires the coupler to be additionally inserted, a size of the system may increase and an insertion loss caused by the coupler may increase, and thus, there may be a problem that overall system performance is degraded.

### SUMMARY

The disclosure has been developed to address the above-discussed deficiencies of the prior art, and an object of the present disclosure is to provide a method for enhancing performance of a self-diagnostic apparatus, which grasps and diagnoses respective operation states of channels in a beamforming system having a plurality of channels, while reducing a size of the self-diagnostic apparatus.

According to an embodiment of the disclosure to achieve the above-described object, a self-diagnostic apparatus includes: a signal detection line which is magnetic-coupled with an RF signal line through a magnetic coupling loop; and a signal detector configured to detect a size and a phase of an RF signal by detecting a current flowing through the signal detection line.

The RF signal line may be a signal line that connects an antenna and a transceiver. The signal detection line may be formed to be orthogonal to the RF signal line.

The magnetic coupling loop may intersect while forming a loop on both sides of the RF signal line.

The magnetic coupling loop may be formed on both sides of the RF signal line in parallel with the RF signal line.

The magnetic coupling loop may be formed to intersect with the RF signal line, while being spaced apart from a lower portion of the RF signal line by a predetermined gap.

According to an embodiment of the disclosure, the self-diagnostic apparatus may further include a signal controller configured to control a beamforming module, based on the size and the phase of the RF signal detected

According to another embodiment of the disclosure, a self-diagnostic method may include: detecting a current flowing through a signal detection line which is magnetic-coupled with an RF signal through a magnetic coupling loop; and detecting a size and a phase of an RF signal from the detected current flowing through the signal detection line.

According to various embodiments of the disclosure described above, the apparatus may grasp and diagnose respective operation states of channels by itself in a beamforming system, without increasing and a size of the system and degrading performance.

In addition, the apparatus may be simply utilized for calibrating to match sizes and phases of signals between adjacent channels, and stability in a beamforming system which is operated for a long time may be enhanced and maintenance may be easily performed.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a block diagram of a related-art beamforming system;

FIG. 2 is a block diagram of a beamforming system having a self-diagnostic circuit;

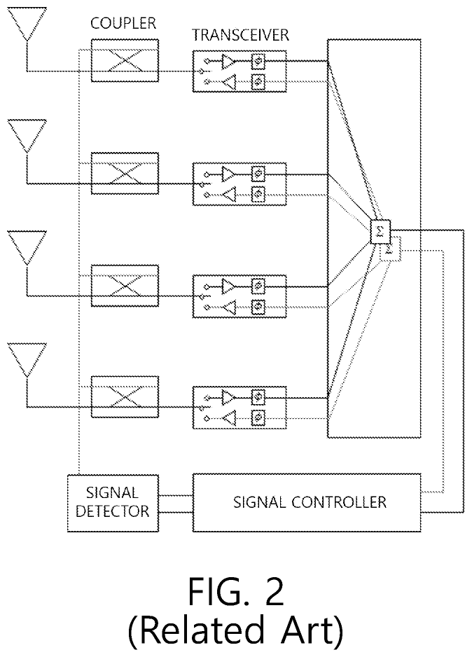

FIG. 3 is a view illustrating a signal detection line for a self-diagnostic apparatus of a magnetic coupling type according to an embodiment of the disclosure;

FIG. 4 is a top view illustrating the structure of FIG. 3 as viewed above;

FIG. 5 is a bottom view illustrating the structure of FIG. 3 as viewed below;

FIG. 6 is a graph showing scattering parameter characteristics of an RF signal line and a signal detection line; and

FIG. 7 is a block diagram of a self-diagnostic apparatus of a magnetic coupling type according to an embodiment of the disclosure.

### DETAILED DESCRIPTION

Hereinafter, the disclosure will be described in detail with reference to the accompanying drawings.

Embodiments of the disclosure propose a self-diagnostic apparatus of a magnetic coupling type. In detecting a current flowing through an RF signal line to grasp a size and a phase of an RF signal, a magnetic induction method using a loop-type coupling line is used.

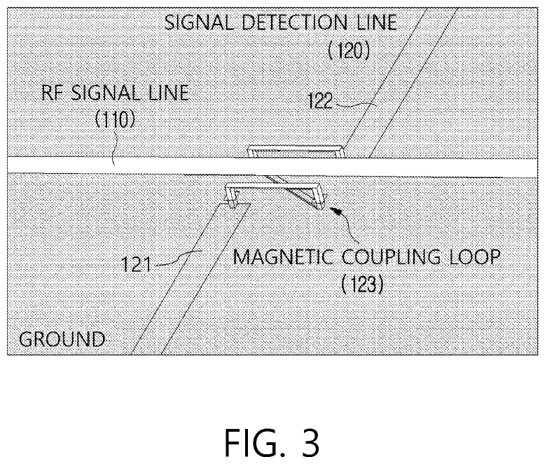

FIG. 3 illustrates a structure of a signal detection line 120 for the self-diagnostic apparatus of the magnetic coupling type according to an embodiment.

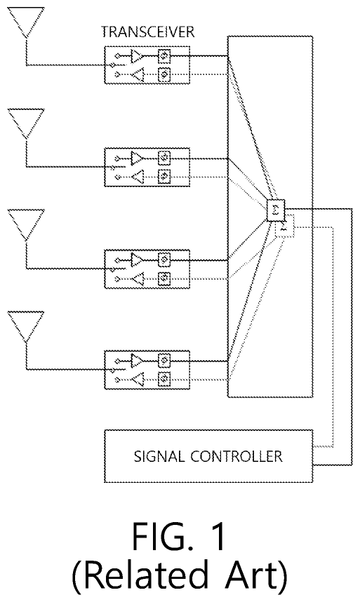

The signal detection line 120 is a line that is magnetic-coupled with an RF signal line 110 in order to detect a current flowing through the RF signal line 110. The RF signal line 110 refers to a signal line that connects an antenna and a transceiver (see FIG. 1).

The signal detection line 120 may divided into a line-1 121, a line-2 122, and a magnetic coupling loop 123.

The line-1 121 and the line-2 122 are formed to be orthogonal to the RF signal line 110. The magnetic coupling loop 123 is a line that intersects while forming a loop adjacent to both sides of the RF signal line 110, and is magnetic-coupled with the RF signal line 110.

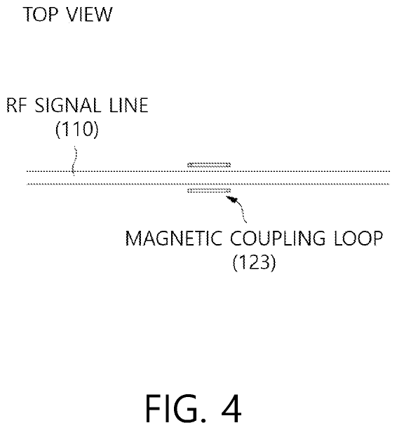

FIG. 4 is a top view illustrating the structure of FIG. 3 as viewed above. As shown in FIGS. 3 and 4, the magnetic coupling loop 123 is formed in parallel with the RF signal line 110 on both sides of the RF signal line 110.

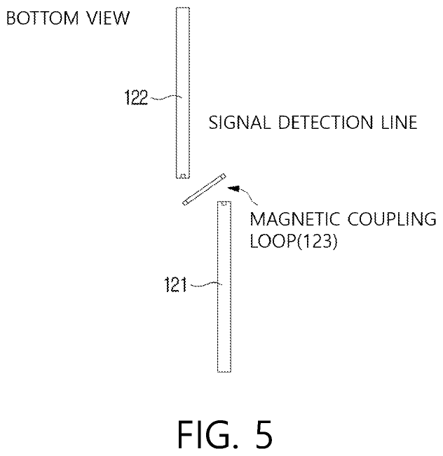

FIG. 5 is a bottom view illustrating the structure of FIG. 3 as viewed below. As shown in FIGS. 3 and 5, the magnetic coupling loop 123 is formed to intersect with the RF signal line 110 while being spaced apart from a lower portion of the RF signal line 110 by a thickness of a substrate.

In addition, the line-1 121 and the line-122 are formed under the RF signal line 110 to be orthogonal to the RF signal line 110.

In FIG. 3, the substrate where the RF signal line 110 and the signal detection line 120 are formed has a microstrip transmission line structures formed thereover/thereunder, thereby forming a 3-layered structure. Accordingly, the magnetic coupling loop 123 should penetrate through an intermediate ground layer, and a small hole may be formed to penetrate through the ground to allow the magnetic coupling loop 123 to pass therethrough and to prevent from being connected with the ground.

When the RF signal line 110 and the signal detection line 120 are implemented according to the structure shown in FIGS. 3 to 5, the signal detection line 120 may detect an RF signal without influencing a transmission characteristic of the RF signal line 110.

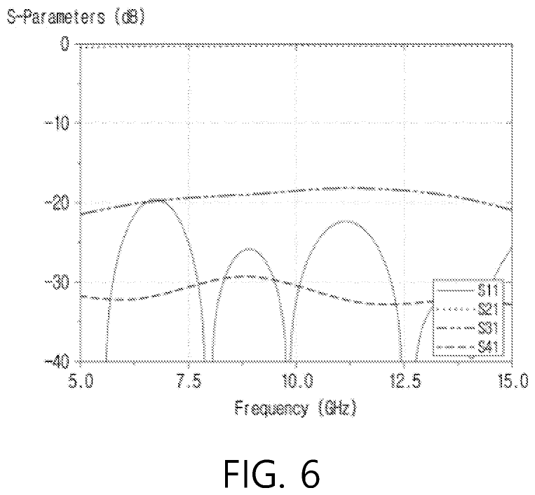

FIG. 6 shows scattering parameter characteristics of the RF signal line 110 and the signal detection line 120 according to the structure shown in FIGS. 3 to 5.

As shown in the drawing, a scattering parameter characteristic S11 of the RF signal line 110 is −20 dB or less, which shows that matching is well maintained. A transmission characteristic S21 of an RF signal shows that signal transmission is smoothly performed. In addition, characteristics S31, S41 of transmission from the RF signal line 110 to the signal detection line 120 are about −20 dB, −30dB, which show good performance.

Through this, it can be seen that the signal detection line 120 to be applied to the self-diagnostic apparatus of the magnetic coupling type according to an embodiment forms a loop around the RF signal line 110, and extracts an RF signal in a broad band without influencing transmission characteristics of an RF signal.

In the above-described embodiment, the signal detection line 120 is implemented as a transmission line of a microstrip form on a printed circuit board (PCB), but the signal detection line 120 may be implemented inside a monolithic microwave integrated circuit (MMIC).

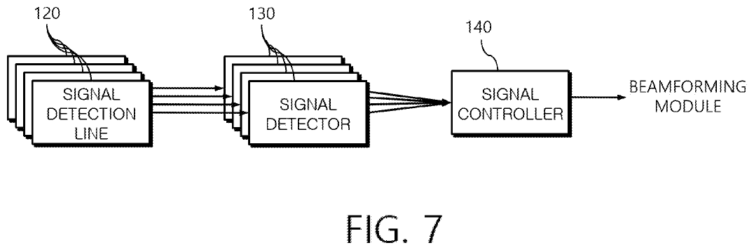

FIG. 7 is a block diagram of a self-diagnostic apparatus of a magnetic coupling type according to an embodiment. As shown in the drawing, the self-diagnostic apparatus of the magnetic coupling type according to an embodiment may include signal detection lines 120, signal detectors 130, and a signal controller 140.

The number of signal detection lines 120 and the number of signal detectors 130 may be determined according to a beamforming structure. That is, as many signal detection lines 120 and signal detectors 130 as the number of antennas and the number of RF transceivers should be provided. In the case of the beamforming system of the structure shown in FIG. 1, four signal detection lines 120 and four signal detectors 130 may be required, respectively.

The signal detection lines 120 have been described in detail with reference to FIGS. 3 to 5. Since the signal detection lines 120 are magnetic-coupled with the RF signal lines 110, a current flows through the signal detection lines 120 due to a change in an electromagnetic field generated around the RF signal lines 110 as a signal passes through the RF signal lines 110.

Specifically, since a current is induced by a change in the electromagnetic field, particularly, a change in the magnetic field caused by a signal passing through the inside of the magnetic coupling loops 123, signals flowing through the RF signal lines 110 may be detected.

The signal detectors 130 may detect RF signals passing through the RF signal lines 110 by detecting currents flowing through the signal detection lines 120, respectively. In addition, the signal detectors 130 detect sizes and phases of the detected RF signals, respectively, and transmit state information of the detected RF signals to the signal controller 140.

The signal controller 140 diagnoses a state of each channel, based on the sizes and the phases of the RF signals which are transmitted through the signal detectors 130, and controls a beamforming module (not shown) to calibrate the state.

Up to now, the self-diagnostic apparatus of the magnetic coupling type which uses a magnetic induction method by using a coupling line of a loop type in detecting a current flowing through the RF signal line to grasp a size and a phase of an RF signal has been described in detail with reference to a preferred embodiment.

In an embodiment, the self-diagnostic apparatus which is capable of grasping and diagnosing an operation state of each channel in a beamforming system having a plurality of channels by itself is proposed, and the apparatus may be applied not only to a diagnostic function of grasping a state of each channel but also to a function of calibrating to match sizes and phases of signals between adjacent channels. In addition, stability in the beamforming system which is operated for a long time may be enhanced and maintenance may be easily performed.

The self-diagnostic apparatus of the magnetic coupling type according to an embodiment may be utilized in an RF/microwave circuit for wireless communication, an MMIC component and an antenna transceiving system, and in particular, is applicable to a next-generation beamforming system such as a 5G system and a satellite communication system.

In addition, while preferred embodiments of the present disclosure have been illustrated and described, the present disclosure is not limited to the above-described specific embodiments. Various changes can be made by a person skilled in the art without departing from the scope of the present disclosure claimed in claims, and also, changed embodiments should not be understood as being separate from the technical idea or prospect of the present disclosure.

What is claimed is:

1. A self-diagnostic apparatus comprising:
a signal detection line which is magnetic-coupled with an RF signal line through a magnetic coupling loop; and
a signal detector configured to detect a size and a phase of an RF signal by detecting a current flowing through the signal detection line.

2. The self-diagnostic apparatus of claim 1, wherein the RF signal line is a signal line that connects an antenna and a transceiver.

3. The self-diagnostic apparatus of claim 1, wherein the signal detection line is formed to be orthogonal to the RF signal line.

4. The self-diagnostic apparatus of claim 3, wherein the magnetic coupling loop intersects while forming a loop on both sides of the RF signal line.

5. The self-diagnostic apparatus of claim 3, wherein the magnetic coupling loop is formed on both sides of the RF signal line in parallel with the RF signal line.

6. The self-diagnostic apparatus of claim 4, wherein the magnetic coupling loop is formed to intersect with the RF signal line, while being spaced apart from a lower portion of the RF signal line by a predetermined gap.

7. The self-diagnostic apparatus of claim 1, further comprising a signal controller configured to control a beamforming module, based on the size and the phse of the RF signal detected.

8. A self-diagnostic method comprising:
detecting a current flowing through a signal detection line which is magnetic-coupled with an RF signal through a magnetic coupling loop; and
detecting a size and a phase of an RF signal from the detected current flowing through the signal detection line.
